(19) United States
(12) Patent Application Publication
(10) Pub. No.: US 2023/0130726 A1
(43) Pub. Date: Apr. 27, 2023

(54) Silicon Carbide Trench Gate MOSFET and Method for Manufacturing Thereof

(71) Applicant: ZJU-Hangzhou Global Scientific and Technological Innovation Center, Hangzhou (CN)

(72) Inventors: Kuang SHENG, Hangzhou (CN); Na REN, Hangzhou (CN); Hongyi XU, Hangzhou (CN); Chongyu JIANG, Hangzhou (CN)

(21) Appl. No.: 17/971,665

(22) Filed: Oct. 24, 2022

(30) Foreign Application Priority Data
Oct. 25, 2021 (CN) 202111239940.2

(51) Int. Cl. H01L 29/06; H01L 29/16; H01L 29/10; H01L 29/78; H01L 21/04; H01L 29/66

(52) U.S. Cl. CPC H01L 29/063; H01L 21/0465; H01L 29/1095; H01L 29/1608; H01L 29/7813; H01L 29/66068

(57) ABSTRACT

The present disclosure provides a silicon carbide trench gate metal oxide semiconductor field effect transistor (MOSFET) and a method for manufacturing thereof. The silicon carbide trench gate MOSFET includes: a substrate having a first doping type, an epitaxial layer formed on the substrate and having the first doping type, an epitaxial well region formed above the epitaxial layer and having a second doping type, a first source contact region formed in the epitaxial well region and having the first doping type, a second source contact region formed in the epitaxial well region and having the second doping type, a trench gate, a source electrode and a drain electrode, wherein the trench gate includes a gate dielectric and a gate electrode, the silicon carbide trench gate MOSFET further includes a injection-type current diffusion region, which is wrapped around the bottom of the trench gate and has the first doping type.

### CROSS-REFERENCE TO RELATED APPLICATIONS

The present disclosure claims the priority of Chinese Patent Application No. 202111239940.2, filed to the China National Intellectual Property Administration on Oct. 25, 2021 and entitled “Silicon Carbide Trench Gate MOSFET and Method for Manufacturing Thereof”, which is incorporated herein its entirety by reference.

### TECHNICAL FIELD

The present disclosure relates to a semiconductor device, and in particular, to a silicon carbide trench gate metal oxide semiconductor field effect transistor (MOSFET) and a method for manufacturing thereof.

### BACKGROUND

The performance of traditional silicon-based semiconductor devices has gradually approached to a physical limit of the material, and third-generation power semiconductor devices using a SiC material have a strong attractive force in high-power density and high-efficiency devices due to their excellent characteristics such as high frequency, high voltage and strong thermal conductivity. SiC MOSFET devices are gradually used in application scenarios such as electric vehicles and photovoltaic inverters due to their easy driving and high switching frequency. The SiC MOSFET devices mainly include right plane gate double-diffusion SiC MOSFETs and trench gate MOSFETs. Compared with the plane gate MOSFETs, the trench gate MOSFETs eliminate JFET region resistance and have higher channel density at the same time, such that the on-state characteristic resistance of the devices is greatly reduced. At the same time, due to the crystal orientation of the material, sidewalls of a trench have relatively excellent channel electron mobility.

However, there are still several problems in the actual fabrication and application of SiC trench MOSFET devices: (1) a high electric field in an SiC drift region causes an extremely high electric field on a gate dielectric, and this problem is aggravated at trench corners, therefore a high drain voltage causes a rapid breakdown of the gate dielectric; and (2) due to the relatively small on-resistance of a trench MOSFET, circuit current is relatively large when a short circuit occurs, the device heats up seriously, and the short circuit capability is weaker than that of the plane gate MOSFET. Therefore, it is necessary to optimize the structure, so as to avoid premature breakdown at the bottom of the gate trench. A conventional trench gate SiC MOSFET cell described in the structure shown in FIG. 1 protects the gate dielectric by way of injecting a second doping type (e.g., P-type) into the bottom. The structure includes a silicon carbide substrate region 001 having a first doping type, a silicon carbide epitaxial region 002 having the first doping type (e.g., N-type), a silicon carbide epitaxial well region 003 having a second doping type, a source contact region 004 having the second doping type, a source contact region 005 having the first doping type, a trench gate dielectric 006, an electric field shielding region 007 having the second doping type (which is generally a heavily doped P-type region), a trench gate electrode 008, a drain electrode 010, and a source electrode 011. When the conventional trench gate MOSFET device is turned on (a positive voltage is applied to the trench gate electrode 008, such as 10-20 V, a positive voltage is applied to the drain electrode 010, such as 0-20 V, and a zero voltage is applied to the source electrode 011, such as 0 V), a current path is shown as Ia in FIG. 2, and channels 009 are formed on both sides of the trench to control the on/off of the device. The current classical trench MOSFET structure can alleviate the electric fields at the trench corners, but cannot improve its short circuit capability.

### SUMMARY

The present disclosure provides a silicon carbide trench gate metal oxide semiconductor field effect transistor (MOSFET) and a method for manufacturing thereof.

According to an embodiment of the present disclosure, a silicon carbide trench gate MOSFET is provided, including: a substrate having a first doping type, an epitaxial layer formed on the substrate and having the first doping type, an epitaxial well region formed above the epitaxial layer and having a second doping type, a first source contact region formed in the epitaxial well region and having the first doping type, a second source contact region formed in the epitaxial well region and having the second doping type, a trench gate formed in the epitaxial well region, a source electrode formed on a side of the epitaxial well region away from the epitaxial layer, and a drain electrode formed on a side of the substrate away from the epitaxial layer, wherein the trench gate includes a gate dielectric and a gate electrode, and the silicon carbide trench gate MOSFET further includes: a injection-type current diffusion region, which is wrapped around a bottom of the trench gate, and has a concave shape and the first doping type, wherein a bottom of the injection-type current diffusion region is not higher than a bottom of the epitaxial well region, a doping concentration of the injection-type current diffusion region is higher than a doping concentration of the epitaxial layer and a doping concentration of the epitaxial well region, the injection-type current diffusion region is in direct contact with the epitaxial well region, and the bottom of the epitaxial well region is lower than the bottom of the trench gate.

According to another embodiment of the present disclosure, a silicon carbide trench gate MOSFET is provided, including: a substrate having a first doping type, an epitaxial layer formed on the substrate and having the first doping type, an epitaxial well region formed on the epitaxial layer and having a second doping type, a first source contact region formed in the epitaxial well region and having the first doping type, a second source contact region formed in the epitaxial well region and having the second doping type, a trench gate formed in the epitaxial well region, a source electrode formed on a side of the epitaxial well region away from the epitaxial layer, and a drain electrode formed on a side of the substrate away from the epitaxial layer, wherein the trench gate includes a gate dielectric and a gate electrode, and the silicon carbide trench gate MOSFET further includes: a injection-type current diffusion region, which is wrapped around the bottom of the trench gate, and has a concave shape and the first doping type, wherein a bottom of the injection-type current diffusion region is not higher than a bottom of the epitaxial well region, and a doping concentration of the injection-type current diffusion region is higher than a doping concentration of the epitaxial layer and a doping concentration of the epitaxial well region; and epitaxial protection regions, which are formed on both sides of the injection-type current diffusion region and at the bottom of the epitaxial well region, and have the second doping type, wherein a doping concentration of the epitaxial protection region is higher than the doping concentration of the epitaxial well region, the injection-type current diffusion region is connected to the epitaxial well region through the epitaxial protection region, and a bottom of the epitaxial protection region is lower than the bottom of the trench gate.

According to yet another embodiment of the present disclosure, a silicon carbide trench gate MOSFET is provided, including: a substrate having a first doping type, an epitaxial layer formed on the substrate and having the first doping type, an epitaxial well region formed on the epitaxial layer and having a second doping type, a first source contact region formed in the epitaxial well region and having the first doping type, a second source contact region formed in the epitaxial well region and having the second doping type, a trench gate formed in the epitaxial well region, a source electrode formed on a side of the epitaxial well region away from the epitaxial layer, and a drain electrode formed on a side of the substrate away from the epitaxial layer, wherein the trench gate includes a gate dielectric and a gate electrode, and the silicon carbide trench gate MOSFET further includes: a injection-type current diffusion region, which is wrapped around the bottom of the trench gate, and has a concave shape and the first doping type, wherein a bottom of the injection-type current diffusion region is not higher than a bottom of the epitaxial well region, and a doping concentration of the injection-type current diffusion region is higher than a doping concentration of the epitaxial layer and a doping concentration of the epitaxial well region; epitaxial protection regions, which are formed on both sides of the injection-type current diffusion region and at the bottom of the epitaxial well region, and have the second doping type, wherein a doping concentration of the epitaxial protection region is higher than the doping concentration of the epitaxial well region, the injection-type current diffusion region is connected to the epitaxial well region through the epitaxial protection region, and a bottom of the epitaxial protection region is lower than the bottom of the trench gate; and an epitaxial current diffusion region, which is formed above the epitaxial protection region and in the epitaxial well region, and has the first doping type, wherein the epitaxial current diffusion region is in direct contact with sidewalls on the both sides of the trench gate.

According to yet another embodiment of the present disclosure, a method for manufacturing a silicon carbide trench gate MOSFET is provided, including: an epitaxial layer on a substrate is formed; an epitaxial well region on the epitaxial layer is formed; a first source contact region is formed in the epitaxial well region; a second source contact region is formed in the epitaxial well region; a trench on a semiconductor surface of the semiconductor surface is etched; ion injection is performed by using a mask of the trench, so as to form an injection-type current diffusion region that is wrapped around the bottom of the trench, wherein the bottom of the injection-type current diffusion region is not higher than that of the epitaxial well region, and the doping concentration of the injection-type current diffusion region is higher than the doping concentration of the epitaxial layer and the doping concentration of the epitaxial well region; a gate dielectric is formed on the surface of the trench; the trench is filled with a gate electrode; a drain electrode is formed on a side of the substrate away from the epitaxial layer; and a source electrode is formed on a side of the substrate away from the epitaxial layer, wherein the substrate, the epitaxial layer, the first source contact region and the injection-type current diffusion region have a first doping type, and the epitaxial well region and the second source contact region have a second doping type.

### BRIEF DESCRIPTION OF THE DRAWINGS

FIG. 1 is a schematic structural diagram of a cell 000 of a conventional silicon carbide trench gate MOSFET device;

FIG. 2 is a schematic diagram of a current path of the cell 000 of the conventional silicon carbide trench gate MOSFET device in a conduction state;

FIG. 3 is a schematic structural diagram of a first cell 100 of a silicon carbide trench gate MOSFET device of the present disclosure;

FIG. 4 is a diagram showing a current path and an internal state change of the first cell 100 of the silicon carbide trench gate MOSFET device of the present disclosure in a forward conduction state;

FIG. 5 is a schematic structural diagram of a second cell 200 of a silicon carbide polygonal trench gate MOSFET device derived from the first cell 100 according to the present disclosure;

FIG. 6 is a schematic structural diagram of a third cell 300 of a silicon carbide rounded rectangular trench gate MOSFET device derived from the first cell 100 according to the present disclosure;

FIG. 7 is a schematic structural diagram of a fourth cell 400 of a silicon carbide U-shaped trench gate MOSFET device derived from the first cell 100 according to the present disclosure;

FIG. 8 is a schematic structural diagram of a fifth cell 500 of a discrete trench gate MOSFET device derived from the first cell 100 according to the present disclosure;

FIG. 9 is a schematic structural diagram of a sixth cell 600 of a discrete trench gate MOSFET device derived from the second cell 200 according to the present disclosure;

FIG. 10 is a schematic structural diagram of a seventh cell 700 of a discrete trench gate MOSFET device derived from the third cell 300 according to the present disclosure;

FIG. 11 is a schematic structural diagram of an eighth cell 800 of a discrete trench gate MOSFET device derived from the fourth cell 400 according to the present disclosure;

FIG. 12 is a schematic structural diagram of a ninth cell 900 of a trench gate MOSFET device, which is provided with a shielding region with a second doping type at the bottom of an injection-type current diffusion region and is derived from the first cell 100 according to the present disclosure;

FIG. 13 is a schematic diagram of a tenth cell 1000 of a cell structure of a trench gate MOSFET device, which is provided with a shielding region with a second doping type at the bottom of an injection-type current diffusion region and is derived from the second cell 200 according to the present disclosure;

FIG. 14 is a schematic diagram of an eleventh cell 1100 of a cell structure of a trench gate MOSFET device, which is provided with a shielding region with a second doping type at the bottom of an injection-type current diffusion region and is derived from the third cell 300 according to the present disclosure;

FIG. 15 is a schematic diagram of a twelfth cell 1200 of a cell structure of a trench gate MOSFET device, which is provided with a shielding region with a second doping type at the bottom of an injection-type current diffusion region and is derived from the fourth cell 400 according to the present disclosure;

FIG. 16 is a schematic diagram of a thirteenth cell 1300 of a trench gate, which is provided with an epitaxial protection region and is derived from the first cell 100 according to the present disclosure;

FIG. 17 is a schematic structural diagram of a fourteenth cell 1400 of a trench gate, which is provided with an epitaxial protection region and is derived from the second cell 200 according to the present disclosure;

FIG. 18 is a schematic structural diagram of a fifteenth cell 1500 of a trench gate, which is provided with an epitaxial protection region and is derived from the third cell 300 according to the present disclosure;

FIG. 19 is a schematic structural diagram of a sixteenth cell 1600 of a trench gate, which is provided with an epitaxial protection region and is derived from the fourth cell 400 according to the present disclosure;

FIG. 20 is a schematic structural diagram of a seventh cell 1700 of a trench gate, which is provided with an epitaxial current diffusion region and is derived from the thirteenth cell 1300 according to the present disclosure;

FIG. 21 is a schematic structural diagram of an eighteenth cell 1800 of trench gate, which is provided with an epitaxial current diffusion region and is derived from the fourteenth cell 1400 according to the present disclosure;

FIG. 22 is a schematic structural diagram of a nineteenth cell 1900 of a trench gate, which is provided with an epitaxial current diffusion region and is derived from the fifteenth cell 1500 of the present disclosure;

FIG. 23 is a schematic structural diagram of a twentieth cell 2000 of a trench gate, which is provided with an epitaxial current diffusion region and is derived from the sixteenth cell 1600 according to the present disclosure;

FIG. 24 is a schematic diagram of a twenty-first cell 2100 of a trench gate in which a third source contact region is derived from the seventeenth cell 1700 according to the present disclosure;

FIG. 25 is a schematic diagram of a twenty-second trench gate cell 2200 in which a third source contact region is derived from the eighteenth cell 1800 according to the present disclosure;

FIG. 26 is a schematic diagram of a twenty-third trench gate cell 2300 in which a third source contact region is derived from the nineteenth cell 1900 according to the present disclosure;

FIG. 27 is a schematic diagram of a twenty-fourth trench gate cell 2400 in which a third source contact region is derived from the twentieth cell 2000 according to the present disclosure; and

FIG. 28 is a schematic diagram 2500 of a manufacturing process of a silicon carbide trench MOSFET device according to an embodiment of the present disclosure.

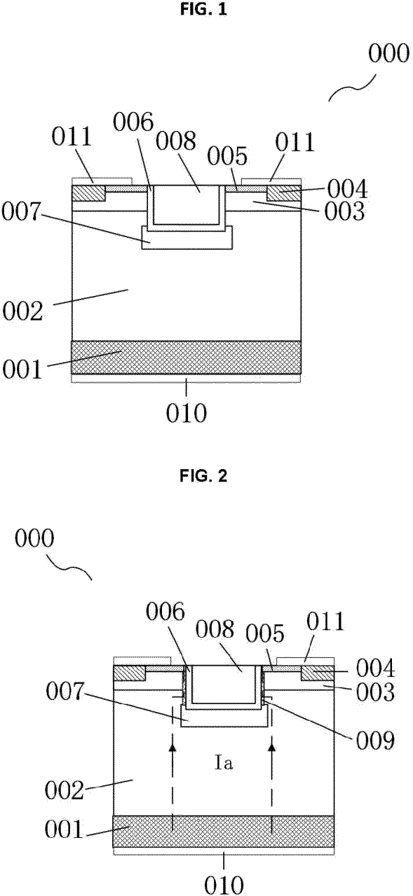

### DETAILED DESCRIPTION OF THE EMBODIMENTS

The specific embodiments of the present disclosure will be described in detail below in combination with the drawings. It should be noted that, the embodiments described herein are only used for illustration, rather than limiting the present disclosure. In the following descriptions, numerous specific details are set forth in order to facilitate a thorough understanding of the present disclosure. However, those of ordinary skill in the art may understand that, these specific details are not required to implement the present disclosure. In addition, in some embodiments, well-known circuits, materials or methods have not been described in detail, in order to avoid obscuring the present disclosure.

Throughout the specification, references to “one embodiment,” “embodiment,” “an example,” or “example” mean that a particular feature, structure or characteristic described in combination with the embodiment or example is contained in at least one embodiment of the present disclosure. Thus, phrases “in one embodiment,” “in the embodiment,” “one example,” or “example” appearing in various places throughout the specification are not necessarily all referring to the same embodiment or example. Furthermore, the particular feature, structure or characteristic may be combined in one more embodiments or examples by any suitable combinations and/or sub-combinations. In addition, those of ordinary skill in the art should understand that, the drawings provided herein are all for illustrative purposes, wherein the same reference signs denote the same elements, but are not limited to, the elements must be completely the same in structure. As used herein, the term “and/or” includes any and all combinations of one or more of relevant listed items.

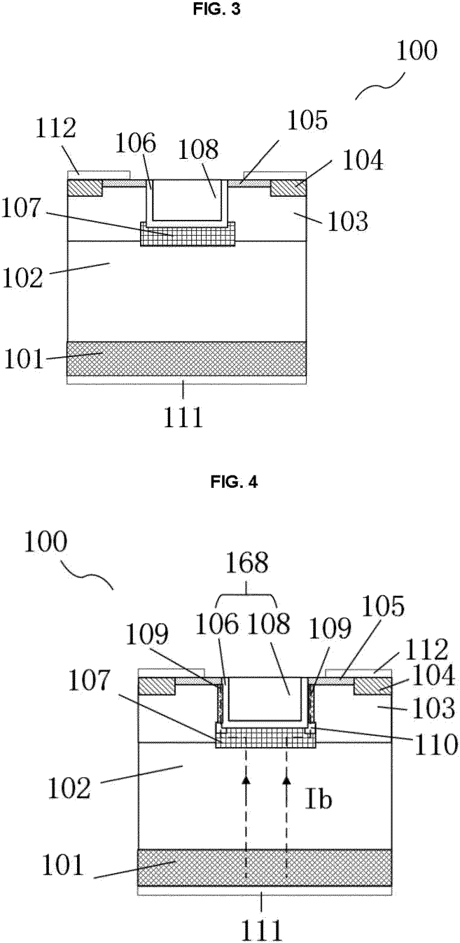

A first doping type referred to in the present disclosure is opposite to a second doping type, when the first doping type is N-type, the second doping type is P-type, and when the first doping type is P-type, the second doping type is N-type. The doping type referred to in the present disclosure includes, but is not limited to, P-type doping or N-type doping. A concave shape referred to in the present disclosure is not limited to the structure as shown in FIG. 3 or FIG. 4, and may also be a concave shape such as a V shape, a U shape, a polygon and a rounded rectangle.

The structure of a first cell 100 of a silicon carbide trench MOSFET device disclosed in the present disclosure is shown in FIG. 3. The cell structure includes: a substrate 101 having a first doping type (e.g., N-type); an epitaxial layer 102 formed on the substrate 101 and having the first doping type; an epitaxial well region 103 formed above the epitaxial layer 102 and having a second doping type (e.g., P-type), wherein in one embodiment, formed above the epitaxial layer 102 means forming a direct contact with the epitaxial layer 102 on the epitaxial layer 102, or means formed above the epitaxial layer 102 and not forming a direct contact with the epitaxial layer 102 (for example, other regions are further arranged there between); a first source contact region 105 formed in the epitaxial well region 103 and having the first doping type; a second source contact region 104 formed in the epitaxial well region 103 and having the second doping type, wherein the second source contact region 104 may be adjacent to the first source contact region 105; a trench gate 168 formed in the epitaxial well region 103, including a gate dielectric 106 and a gate electrode 108 (which may be filled with polysilicon) formed on the gate dielectric 106; an injection-type current diffusion region 107, which is wrapped around the bottom (or the bottom and a bottom side face) of the trench gate 106 and has the first doping type, wherein in one embodiment, the injection-type current diffusion region 107 is wrapped around the bottom and the bottom side face of the trench gate 106 in a concave shape, a bottom of the injection-type current diffusion region 107 is not higher than that of the epitaxial well region 103, so as to ensure normal forward conduction of the device, and a doping concentration of the injection-type current diffusion region 107 is higher than a doping concentration of the epitaxial layer 102 and a doping concentration of the epitaxial well region 103; and a drain electrode 111 formed on a side of the epitaxial well region 103 away from the epitaxial layer 102, and a source electrode 112 formed on a side of the substrate 101 away from the epitaxial layer 102. A conduction current path of current Ib of the silicon carbide trench MOSFET device in a forward conduction state is shown by a dashed line with an arrow in FIG. 4, wherein the arrow points to the flow direction of the current lb. In an embodiment, a positive voltage (e.g.,10-20 V) is applied to the gate electrode 108, a positive voltage (e.g., 0-20 V) is applied to the drain electrode 111, and the source electrode 112 is grounded, in this state, channels 109 are formed on both sides of the trench gate 108 of the silicon carbide trench MOSFET device, accumulation regions 110 are formed in corners on the both sides of a bottom of the trench gate, and the current flows from the drain electrode 111 to the source electrode 112 after passing through the substrate 101, the epitaxial layer 102, the injection-type current diffusion region 107, the accumulation regions 110, the channels 109 and the first source contact region 105. In another embodiment, there is an extreme case where the device is subjected to a high current and a high voltage, when the silicon carbide trench MOSFET device is in a high-voltage blocking condition (e.g., in the case of a blocking voltage of 600 V), the voltage on the gate electrode 108 becomes high (e.g., 20 V), the channels 109 are opened, and the device is turned on. At this time, the device will have a high electric field due to the existence of a depletion region, and meanwhile, a short circuit is generated by the high current resulting from conduction, wherein a peak value of the electric field is at a central position of the gate dielectric 106 at the bottom of the trench gate 168, a peak value of the current Ib is on the both sides of the trench gate 168, and this structure of the first cell 100 can reduce heat generation during a short circuit process.

Please refer to FIG. 5, it shows a second cell 200 of a silicon carbide polygonal trench gate MOSFET derived from the first cell 100 according to the present disclosure. The difference from the first cell 100 is that the second cell 200 has a polygonal trench gate 168 (which includes a polygonal gate dielectric 106 and a gate electrode 108) and a polygonal injection-type current diffusion region 107. The inclined trench gate 168 of the second cell 200 may facilitate vertical injection to form the injection-type current diffusion region 107.

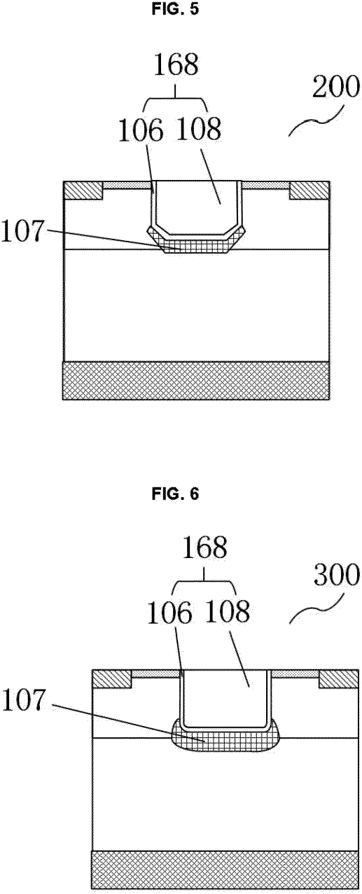

Please refer to FIG. 6, it shows the structure of a third cell 300 of a silicon carbide rounded rectangular trench gate MOSFET derived from the first cell 100 according to the present disclosure. The difference from the first cell 100 is that the third cell 300 has a rounded rectangular trench gate 168 (which includes a rounded rectangular gate dielectric 106 and a gate electrode 108) and a rounded rectangular injection-type current diffusion region 107. The rounded rectangular trench gate 168 of the third cell 300 may facilitate vertical injection to form the injection-type current diffusion region 107.

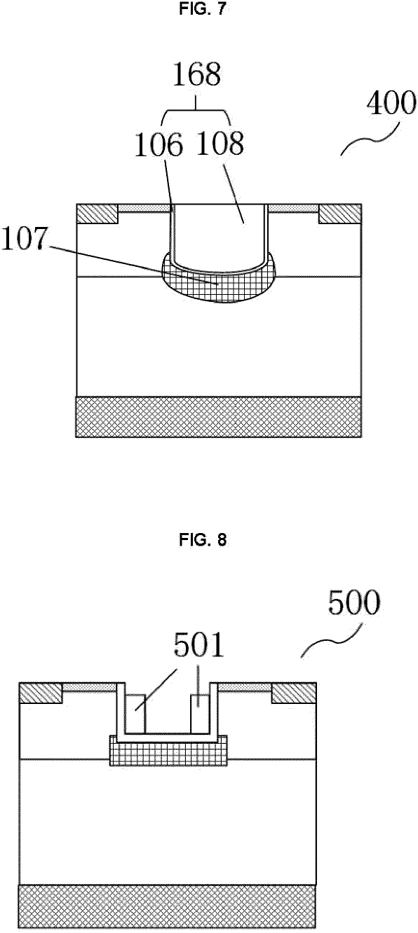

Please refer to FIG. 7, it shows the structure of a fourth cell 400 of a silicon carbide U-shaped trench gate MOSFET derived from the first cell 100 according to the present disclosure. The difference from the first cell 100 is that the fourth cell 400 has a U-shaped trench gate 168 (which includes a U-shaped gate dielectric 106 and a gate electrode 108) and a U-shaped injection-type current diffusion region 107. The U-shaped trench gate 168 of the fourth cell 400 may facilitate vertical injection to form the injection-type current diffusion region 107.

Please refer to FIG. 8, it shows the structure of a fifth cell 500 of a silicon carbide discrete trench gate MOSFET derived from the first cell 100 according to the present disclosure. The difference from the first cell 100 is that the fifth cell 500 includes a polysilicon split gate 501 that is formed by maskless etching. By using the split gate 501, the overlapping area of the gate and the drain can be reduced, and gate-drain capacitance can be effectively reduced.

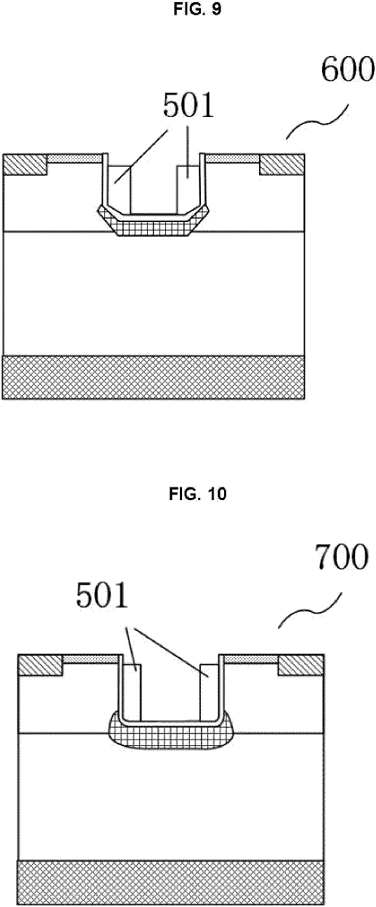

Please refer to FIG. 9, it shows the structure of a sixth cell 600 of a silicon carbide discrete trench gate MOSFET derived from the second cell 200 according to the present disclosure. The difference from the second cell 200 is that the sixth cell 600 includes a polysilicon split gate 501 that is formed by maskless etching. By using the split gate 501, the overlapping area of the gate and the drain can be reduced, and gate-drain capacitance can be effectively reduced.

Please refer to FIG. 10, it shows the structure of a seventh cell 700 of a silicon carbide discrete trench gate MOSFET derived from the third cell 300 according to the present disclosure. The difference from the third cell 300 is that the seventh cell 700 includes a polysilicon split gate 501 that is formed by maskless etching. By using the split gate 501, the overlapping area of the gate and the drain can be reduced, and gate-drain capacitance can be effectively reduced.

Please refer to FIG. 11, it shows the structure of an eighth cell 800 of a silicon carbide discrete trench gate MOSFET derived from the fourth cell 400 of the present disclosure. The difference from the fourth cell 400 is that the eighth cell 800 includes a polysilicon split gate 501 that is formed by maskless etching. By using the split gate 501, the overlapping area of the gate and the drain can be reduced, and gate-drain capacitance can be effectively reduced.

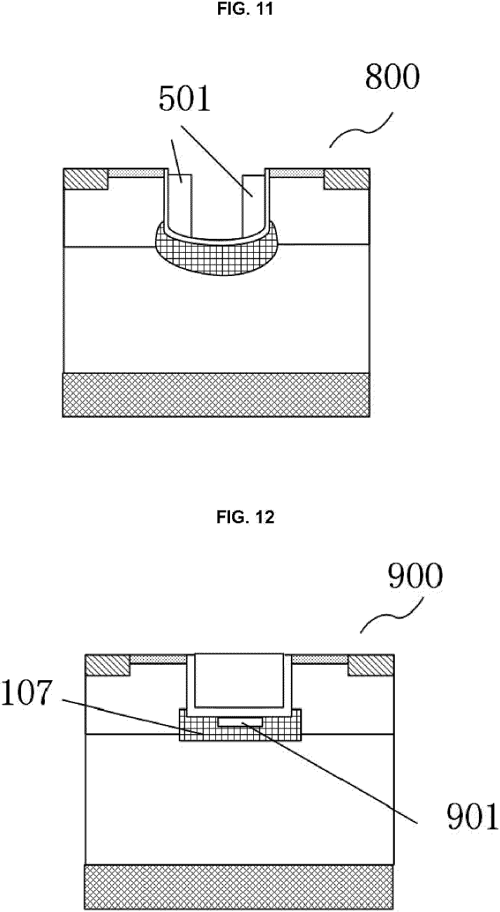

Please refer to FIG. 12, it shows the structure of a ninth cell 900 of the silicon carbide trench gate MOSFET derived from the first cell 100 according to the present disclosure. The difference from the first cell 100 is that the ninth cell 900 further includes a shielding region 901, which is formed in the injection-type current diffusion region 107 and has the second doping type, and the injection depth of the shielding region 901 is continuously adjustable, such that the electric field of the gate dielectric can be effectively reduced.

Please refer to FIG. 13, it shows the structure of a tenth cell 1000 of the silicon carbide trench gate MOSFET derived from the second cell 200 according to the present disclosure. The difference from the second cell 200 is that the tenth cell 1000 further includes a shielding region 901, which is formed in the injection-type current diffusion region 107 and has the second doping type, and the injection depth of the shielding region 901 is continuously adjustable, such that the electric field of the gate dielectric can be effectively reduced.

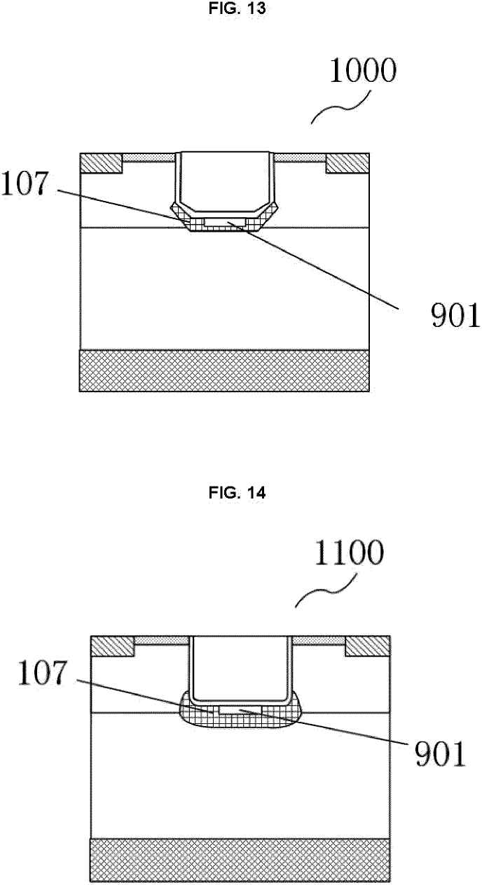

Please refer to FIG. 14, it shows the structure of an eleventh cell 1100 of the silicon carbide trench gate MOSFET derived from the third cell 300 according to the present disclosure. The difference from the third cell 300 is that the eleventh cell 1100 further includes a shielding region 901, which is formed in the injection-type current diffusion region 107 and has the second doping type, and the injection depth of the shielding region 901 is continuously adjustable, such that the electric field of the gate dielectric can be effectively reduced.

Please refer to FIG. 15, it shows the structure of a twelfth cell 1200 of the silicon carbide trench gate MOSFET derived from the fourth cell 400 according to the present disclosure. The difference from the fourth cell 400 is that the twelfth cell 1200 further includes a shielding region 901, which is formed in the injection-type current diffusion region 107 and has the second doping type, and the injection depth of the shielding region 901 is continuously adjustable, such that the electric field of the gate dielectric can be effectively reduced.

In the embodiments shown in FIG. 4 to FIG. 15, the injection-type current diffusion region 107 is in direct contact with the epitaxial well region 103 (for example, the both sides of the injection-type current diffusion region 107 are in direct contact with the epitaxial well region 103), and a bottom of the epitaxial well region 103 is lower than that of the trench gate 168, so as to ensure that when the device is working in a forward conduction manner, a channel is formed in the epitaxial well region 103 on the sidewall of the trench gate, and carries in the channel enter the injection-type current diffusion region.

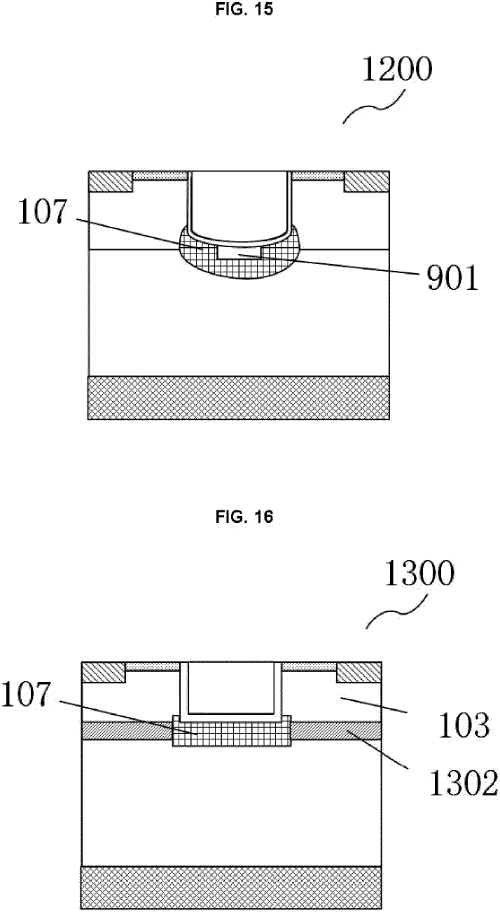

Please refer to FIG. 16, it shows the structure of a thirteenth cell 1300 of the silicon carbide trench gate MOSFET derived from the first cell 100 according to the present disclosure. The difference from the first cell 100 is that the thirteenth cell 1300 further includes epitaxial protection regions 1302, which are formed on the both sides of the injection-type current diffusion region 107 and at the bottom of the epitaxial well region 103, the epitaxial protection region 1302 has the second doping type, and a doping concentration (for example, 1×10¹⁸ cm⁻³ to 3×10¹⁸ cm⁻³) of the epitaxial protection region 1302 is higher than the doping concentration (for example, 1×10¹⁷ cm⁻³ to 1×10¹⁸ cm⁻³) of the epitaxial well region 103. The epitaxial protection region 1302 can effectively reduce the electric field of the gate dielectric, and can play a better role in suppressing the short circuit of the device at the same time.

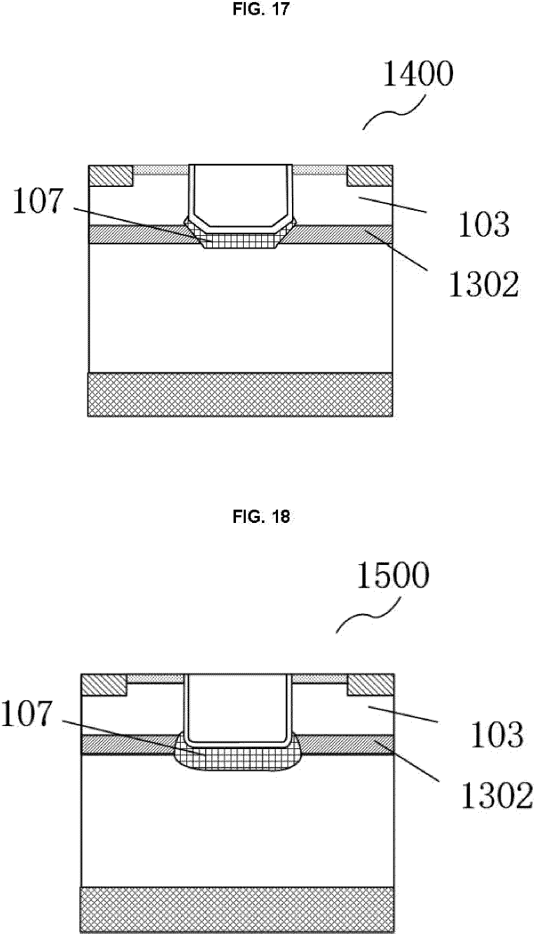

Please refer to FIG. 17, it shows the structure of a fourteenth cell 1400 of the silicon carbide trench gate MOSFET derived from the second cell 200 according to the present disclosure. The difference from the second cell 200 is that the fourteenth cell 1400 further includes epitaxial protection regions 1302, which are formed on the both sides of the injection-type current diffusion region 107 and at the bottom of the epitaxial well region 103, the epitaxial protection region 1302 has the second doping type, and the doping concentration of the epitaxial protection region 1302 is higher than the doping concentration of the epitaxial well region 103. The epitaxial protection region 1302 can effectively reduce the electric field of the gate dielectric, and can play a better role in suppressing the short circuit of the device at the same time.

Please refer to FIG. 18, it shows the structure of a fifteenth cell 1500 of the silicon carbide trench gate MOSFET derived from the third cell 300 according to the present disclosure. The difference from the third cell 300 is that the fifteenth cell 1500 further includes epitaxial protection regions 1302, which are formed on the both sides of the injection-type current diffusion region 107 and at the bottom of the epitaxial well region 103, the epitaxial protection region 1302 has the second doping type, and the doping concentration of the epitaxial protection region 1302 is higher than the doping concentration of the epitaxial well region 103. The epitaxial protection region 1302 can effectively reduce the electric field of the gate dielectric, and can play a better role in suppressing the short circuit of the device at the same time.

Please refer to FIG. 19, it shows the structure of a sixteenth cell 1600 of the silicon carbide trench gate MOSFET derived from the fourth cell 400 according to the present disclosure. The difference from the fourth cell 400 is that the sixteenth cell 1600 further includes epitaxial protection regions 1302, which are formed on the both sides of the injection-type current diffusion region 107 and at the bottom of the epitaxial well region 103, the epitaxial protection region 1302 has the second doping type, and the doping concentration of the epitaxial protection region 1302 is higher than the doping concentration of the epitaxial well region 103. The epitaxial protection region 1302 can effectively reduce the electric field of the gate dielectric, and can play a better role in suppressing the short circuit of the device at the same time.

In the embodiments shown in FIG. 16 to FIG. 19, the bottom of the injection-type current diffusion region 107 is not higher than that of the epitaxial well region 103, the doping concentration of the injection-type current diffusion region 107 is higher than the doping concentration of the epitaxial layer 102 and the doping concentration of the epitaxial well region 103, and the doping concentration of the epitaxial protection region 1302 is higher than that of the epitaxial well region 103. The injection-type current diffusion region 107 is connected to the epitaxial well region 103 by means of the epitaxial protection region 1302 (for example, the both sides of the injection-type current diffusion region 107 are in direct contact with the epitaxial protection region 1302), and corners above the both sides of the injection-type current diffusion region 107 may be in direct contact with the epitaxial well region 103, and a bottom of the epitaxial protection region 1302 is lower than that of the trench gate 168, so as to ensure that when the device is working in a forward conduction manner, a channel is formed in the epitaxial well region 103 on the sidewall of the trench gate 168, and carries in the channel enter the injection-type current diffusion region 107.

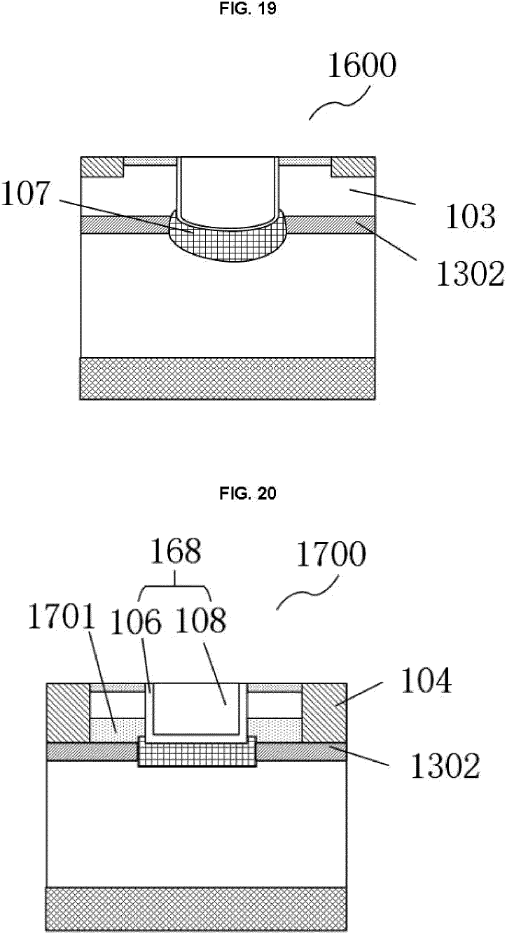

Please refer to FIG. 20, it shows the structure of a seventeenth cell 1700 of a silicon carbide trench gate MOSFET derived from the thirteenth cell 1300 of the present disclosure. The difference from the thirteenth cell 1300 is that the seventeenth cell 1700 further includes an epitaxial current diffusion region 1701, which is formed above the epitaxial protection region 1302 and in the epitaxial well region 103, and the epitaxial current diffusion region 1701 has the first doping type (for example, an N-type doping concentration is 1×10¹⁶ cm⁻³ to 3×10¹⁷ cm⁻³). The epitaxial current diffusion region 1701 can not only diffuse the current of the device, but can also make the corners of the trench gate 168 more stably surrounded by the first doping type (e.g., N-type), and meanwhile, the depth of the second source contact region 104 can continuously extend to form direct contact with the injection-type current diffusion region 107 and the epitaxial protection region 1302, respectively, such that dynamic resistance can be suppressed, and the gate dielectric 106 can be protected.

Please refer to FIG. 21, it shows the structure of an eighteenth cell 1800 of a silicon carbide trench gate MOSFET derived from the fourteenth cell 1400 according to the present disclosure. The difference from the fourteenth cell 1400 is that the eighteenth cell 1800 further includes an epitaxial current diffusion region 1701, which is formed above the epitaxial protection region 1302 and in the epitaxial well region 103, and the epitaxial current diffusion region 1701 has the first doping type. The epitaxial current diffusion region 1701 can not only diffuse the current of the device, but can also make the corners of the trench gate 168 more stably surrounded by the first doping type (e.g., N-type), and meanwhile, the depth of the second source contact region 104 can continuously extend to form direct contact with the injection-type current diffusion region 107 and the epitaxial protection region 1302, respectively, such that dynamic resistance can be suppressed, and the gate dielectric 106 can be protected.

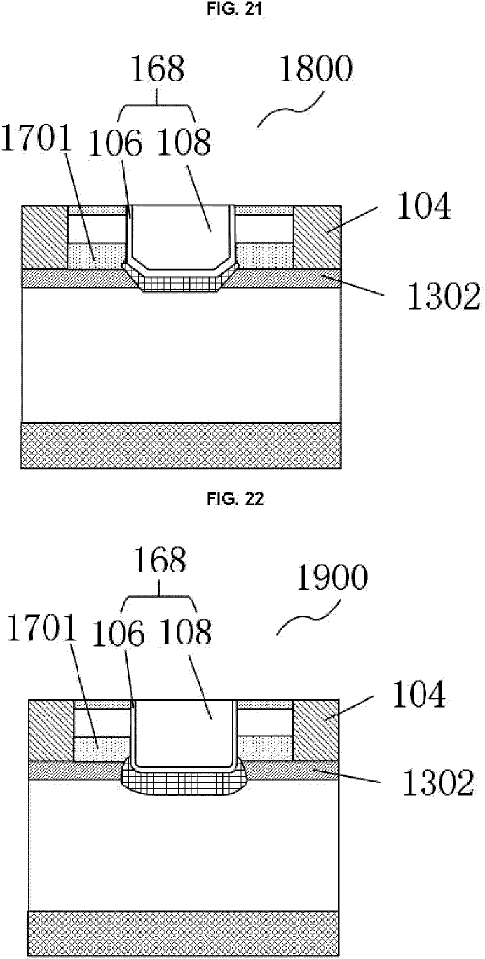

Please refer to FIG. 22, it shows the structure of a nineteenth cell 1900 of a silicon carbide trench gate MOSFET derived from the fifteenth cell 1500 of the present disclosure. The difference from the fifteenth cell 1500 is that the nineteenth cell 1900 further includes an epitaxial current diffusion region 1701, which is formed above the epitaxial protection region 1302 and in the epitaxial well region 103, and the epitaxial current diffusion region 1701 has the first doping type. The epitaxial current diffusion region 1701 can not only diffuse the current of the device, but can also make the corners of the trench gate 168 more stably surrounded by the first doping type (e.g., N-type), and meanwhile, the depth of the second source contact region 104 can continuously extend to form direct contact with the injection-type current diffusion region 107 and the epitaxial protection region 1302, respectively, such that dynamic resistance can be suppressed, and the gate dielectric 106 can be protected.

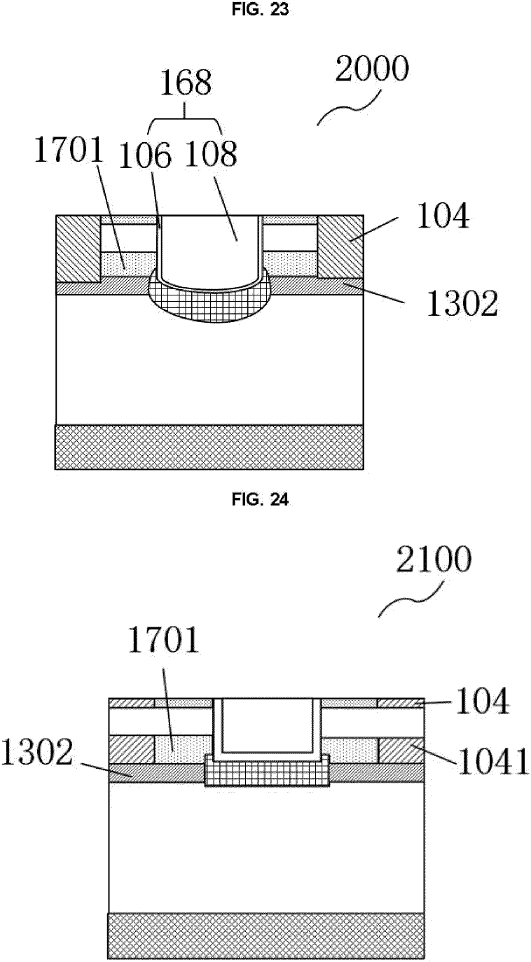

Please refer to FIG. 23, it shows the structure of a twentieth cell 2000 of a silicon carbide trench gate MOSFET derived from the sixteenth cell 1600 according to the present disclosure. The difference from the sixteenth cell 1600 is that the twentieth cell 2000 further includes an epitaxial current diffusion region 1701, which is formed above the epitaxial protection region 1302 and in the epitaxial well region 103, and the epitaxial current diffusion region 1701 has the first doping type. The epitaxial current diffusion region 1701 can not only diffuse the current of the device, but can also make the corners of the trench gate 168 more stably surrounded by the first doping type (e.g., N-type), and meanwhile, the depth of the second source contact region 104 can continuously extend to form direct contact with the injection-type current diffusion region 107 and the epitaxial protection region 1302, respectively, such that dynamic resistance can be suppressed, and the gate dielectric 106 can be protected.

Please refer to FIG. 24, it shows the structure of a twenty-first cell 2100 of a silicon carbide trench gate MOSFET derived from the seventeenth cell 1700 according to the present disclosure. The difference from the seventeenth cell 1700 is that the twenty-first cell 2100 not only includes the second source contact region 104, but also includes a third source contact region 1041, which is formed on the outer side the epitaxial current diffusion region 1701 and above the epitaxial protection region 1302, and the third source contact region may have the same doping type and doping concentration as the second source contact region 104 (e.g., the second doping type, that is, P-type), thereby acting as a buffer circuit to reduce voltage spikes.

Please refer to FIG. 25, it shows the structure of a twenty-second cell 2200 of a silicon carbide trench gate MOSFET derived from the eighteenth cell 1800 according to the present disclosure. The difference from the eighteenth cell 1800 is that the twenty-second cell 2200 not only includes the second source contact region 104, but also includes a third source contact region 1041, which is formed on the outer side the epitaxial current diffusion region 1701 and above the epitaxial protection region 1302, and the third source contact region may have the same doping type and doping concentration as the second source contact region 104 (e.g., the second doping type, that is, P-type), thereby acting as a buffer circuit to reduce voltage spikes.

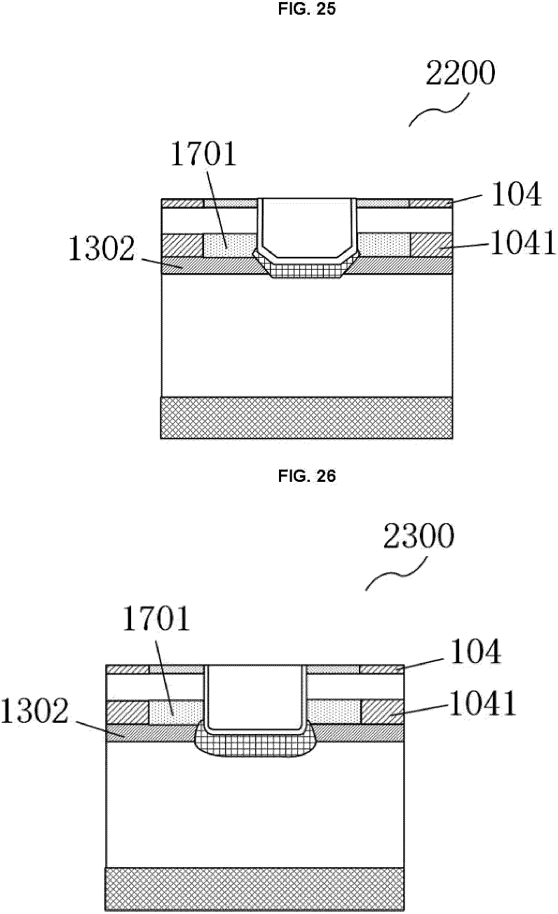

Please refer to FIG. 26, it shows the structure of a twenty-third cell 2300 of a silicon carbide trench gate MOSFET derived from the nineteenth cell 1900 according to the present disclosure. The difference from the nineteenth cell 1900 is that the twenty-third cell 2300 not only includes the second source contact region 104, but also includes a third source contact region 1041, which is formed on the outer side the epitaxial current diffusion region 1701 and above the epitaxial protection region 1302, and the third source contact region may have the same doping type and doping concentration as the second source contact region 104 (e.g., the second doping type, that is, P-type), thereby acting as a buffer circuit to reduce voltage spikes.

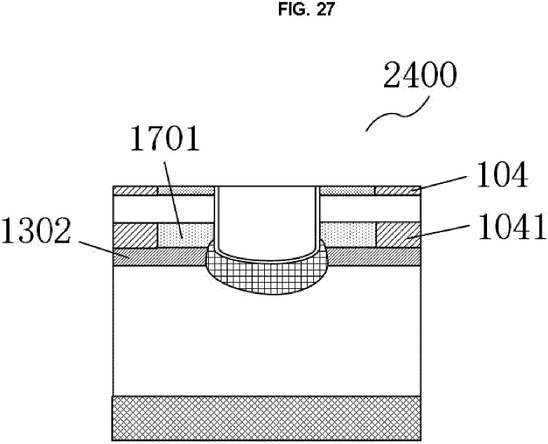

Please refer to FIG. 27, it shows the structure of a twenty-fourth cell 2400 of a silicon carbide trench gate MOSFET derived from the twentieth cell 2000 of the present disclosure. The difference from the twentieth cell 2000 is that the twenty-fourth cell 2400 not only includes the second source contact region 104, but also includes a third source contact region 1041, which is formed on the outer side the epitaxial current diffusion region 1701 and above the epitaxial protection region 1302, and the third source contact region may have the same doping type and doping concentration as the second source contact region 104 (e.g., the second doping type, that is, P-type), thereby acting as a buffer circuit to reduce voltage spikes.

In the embodiments shown in FIG. 20 to FIG. 27, the bottom of the injection-type current diffusion region 107 is not higher than that of the epitaxial well region 103, the doping concentration of the injection-type current diffusion region 107 is higher than the doping concentration of the epitaxial layer 102 and the doping concentration of the epitaxial well region 103, and the doping concentration of the epitaxial protection region 1302 is higher than that of the epitaxial well region 103. The injection-type current diffusion region 107 is connected to the epitaxial well region 103 by means of the epitaxial protection region 1302 and the epitaxial current diffusion region 1701 (for example, the both sides of the injection-type current diffusion region 107 are in direct contact with the epitaxial protection region 1302, and corners above the both sides of the injection-type current diffusion region 107 may be in direct contact with the epitaxial current diffusion region 1701), and the bottom of the epitaxial protection region 1302 is lower than that of the trench gate 168, so as to ensure that when the device is working in the forward conduction manner, a channel is formed in the epitaxial well region 103 on the sidewall of the trench gate 168, and carries in the channel enter the injection-type current diffusion region 107.

In the embodiments shown in FIG. 3 to FIG. 27, the injection-type current diffusion region 107 can be in direct contact with the epitaxial well region 103, or can be connected to the epitaxial well region 103 by means of the epitaxial protection region 1302 or the epitaxial protection region 1302 and the epitaxial current diffusion region 1701, so as to ensure that when the device is working in the forward conduction manner, a channel is formed in the epitaxial well region 103 on the sidewall of the trench gate 168, and carries in the channel enter the injection-type current diffusion region 107.

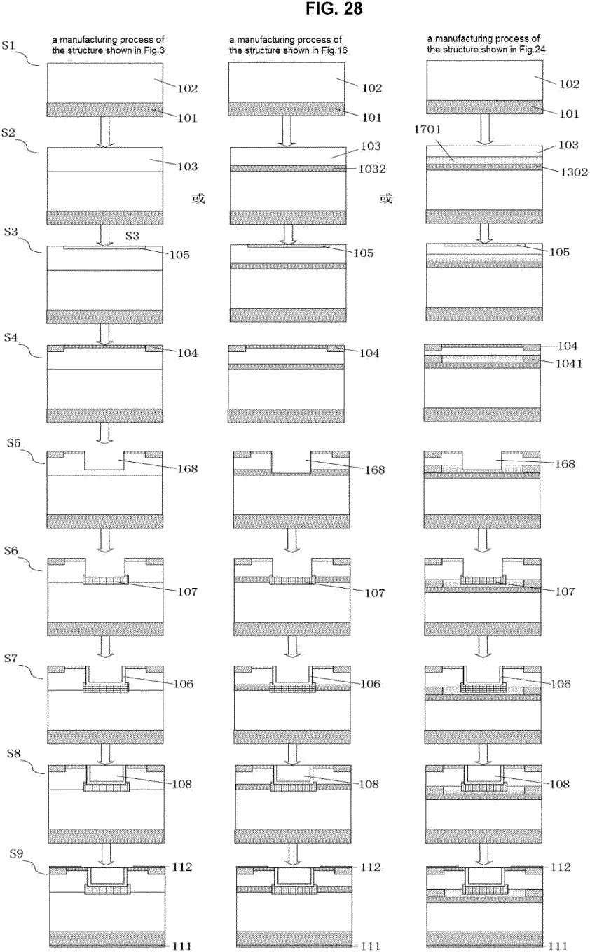

FIG. 28 is a flow diagram of manufacturing the silicon carbide trench gate MOSFET device shown in FIG. 3 according to an embodiment of the present disclosure. The method includes steps S1-S9.

Step S1, the epitaxial layer 102 is formed above the substrate 101 (e.g., growing the epitaxial layer 102 on the surface of the substrate 101). Both the substrate 101 and the epitaxial layer 102 have the first doping type, and a doping concentration of the substrate 101 is higher than that of the epitaxial layer 102.

Step S2, the epitaxial well region 103 is formed above the epitaxial layer 102 (e.g., growing the epitaxial well region 103 on the surface of the epitaxial layer 102). If it is necessary to manufacture a silicon carbide trench gate MOSFET device including the epitaxial protection region 1302 as shown in FIG. 16, the epitaxial protection region 1302 may be grown on the surface of the epitaxial layer at first, and then the epitaxial well region may be further grown on the surface of the epitaxial protection region 1302. If it is necessary to manufacture a silicon carbide trench gate MOSFET device including the epitaxial current diffusion region 1701 as shown in FIG. 24, the epitaxial current diffusion region 1701 may be grown on the surface of the epitaxial protection region 1302 at first, and then the epitaxial well region is grown on the surface of the epitaxial current diffusion region 1701. The epitaxial protection region 1302 having the second doping type is formed in an epitaxial manner, such that the activation rate is easy to control, high-energy injection of the second doping type on the left and right sides of the channel is avoided, and the structure is easy to implement.

Step S3, the first source contact region 105 is formed, for example, forming the first source contact region 105 in the epitaxial well region 103 by injection which connects with a semiconductor surface by injection.

Step S4, the second source contact region 104 is formed, for example, forming the second source contact region 104 in the epitaxial well region 103 by injection which connects with the semiconductor surface. When a silicon carbide trench gate MOSFET device including the third source contact region 1041 as shown in FIG. 24 is manufactured, the second source contact region 104 and the third source contact region 1041 may be simultaneously formed by one ion injection operation.

Step S5, a trench 068 is etched on the semiconductor surface. In one embodiment, the inclination angle of the top of the control groove 068 is controlled to be less than 5°, and a bottom of the trench is concave (which can be V-shaped, U-shaped or rounded rectangular, and so on). In one embodiment, the trench 068 stops in the epitaxial well region 103 having the second doping type; in another embodiment, the trench 068 stops in the epitaxial protection region 1302 having the second doping type; and in another embodiment, the trench 068 stops in the epitaxial current diffusion region 1701 having the first doping type.

Step S6, ion injection is performed by using a mask of the trench to form the injection-type current injection region 107, for example, performing ion injection by using ions of the first doping type and the mask of the trench to form the injection-type current injection region 107. In one embodiment, the injection-type current injection region 107 that is wrapped around the bottom of the trench is formed by utilizing the ejection capability of the injection process and the diffusion ability of doped ions. Compared with the conventional method, the structure and the process generate no waste to the thickness of the epitaxial layer, so the same withstand voltage can be realized by using a thinner epitaxial layer, so as to achieve more optimized device characteristics; and compared with the solution of injecting the ions into a P-type region on the both sides of the trench to protect the gate dielectric, the use of high-energy ion injection can be avoided.

Step S7, the gate dielectric 106 is formed on the surface of the trench 068. In one embodiment, the gate dielectric 106 may be formed by high temperature oxidation and CVD/PVD/ALD processes.

Step S8, the trench 068 is filled with the gate electrode 108. In one embodiment, the gate electrode 108 is polysilicon.

Step S9, the drain electrode 111 is formed on a side of the substrate 101 away from the epitaxial layer 102, and the source electrode 112 is formed on a side of the epitaxial well region 103 away from the epitaxial layer 102. In one embodiment, the drain electrode 111 and the source electrode 112 may be formed by metal sputtering and ohmic contact.

The present disclosure has the following beneficial technical effects:
1. Compared with a conventional MOSFET in which the bottom of the trench gate is provided with a protection region having the second doping type (e.g., P-type), the MOSFET in the present disclosure, which is provided with the injection-type current diffusion region having a concave shape and the first doping type (e.g., N-type), has a greater thickness in an effective drift region and a higher breakdown voltage. At the same time, a channel of an additional accumulation layer that the MOSFET with the injection-type current diffusion region can provide reduces the on-resistance. By means of reasonably setting the injection-type current diffusion region, the saturation current of the device can be limited. Meanwhile, the position of an electric field peak value can be separated from that of a current peak value, such that the heating power can be reduced, and the short circuit capability of the device can be improved;
2. the shape of the injection-type current diffusion region is set to be a concave shape that is wrapped around the bottom of the trench gate, such as a U shape, a V shape, a polygon or a rounded rectangle, which facilitates vertical injection on process to form the current diffusion region, and reduces the difficulty of the process;
3. P-type shielding regions are formed in the injection-type current diffusion region and at the middle of the bottom of the trench gate, such that the electric field of the gate dielectric can be effectively reduced;
4. the epitaxial protection regions are formed on the both sides of the injection-type current diffusion region and at the bottom of the epitaxial well region, such that the electric field of the gate dielectric can be effectively reduced, and meanwhile, a better role in suppressing the short circuit of the device can be realized;
5. the epitaxial current diffusion region is formed above the epitaxial protection regions and below the epitaxial well region, such that the current of the device is diffused, and meanwhile, the corners of the trench gate are wrapped by N-type doping more stably; the bottom of the epitaxial current diffusion region is not higher than that of the trench gate, and the top of the epitaxial current diffusion region is higher than the bottom of the trench gate;
6. in addition to the second source contact region, a third source contact region 1041 can also be arranged on the outer side the epitaxial current diffusion region and above the epitaxial protection region, and can have the same doping type and doping concentration as the second source contact region 104 (e.g., the second doping type, that is, P-type), thereby acting as a buffer circuit to reduce voltage spikes; and
7. in the process flow, the injection-type current diffusion region can be formed by performing ion injection by using the mask of the etched trench. In an actual process, the injection-type current diffusion region wrapping the corners can be formed by the ejection capability of an injection process and the diffusion ability of a doped ion activation process. In the present embodiment, since the injection-type current diffusion region requires high-dose injection (in one embodiment, it needs to be higher than the concentration of the epitaxial well region, and in another embodiment, it needs to be higher than the concentration of the epitaxial protection region), so ions are injected into the corners to generate ejection, such that it is easier to gather doped ions to form a state of wrapping the corners. Compared with the solution of injecting the ions into a P-type region on the both sides of the trench to protect the gate dielectric, the use of high-energy ion injection can be avoided. Compared with the conventional structure, the present embodiment and the matched process generate no waste to the thickness of the epitaxial layer, so the same withstand voltage can be realized by using a thinner epitaxial layer, so as to achieve more optimized device characteristics.

Although the present disclosure has been described with reference to several exemplary embodiments, it should be understood that the terms used are illustrative and exemplary terms, rather than restrictive terms. Since the present disclosure may be specifically implemented in many forms without departing from the spirit or essence of the invention, it should be understood that the above embodiments are not limited to any of the foregoing details, but should be construed broadly within the spirit and scope defined by the appended claims. Therefore, all changes and modifications falling within the scope of the claims or their equivalents should be covered by the appended claims.

1. A silicon carbide trench gate MOSFET, comprising:
a substrate having a first doping type, an epitaxial layer formed on the substrate and having the first doping type, an epitaxial well region formed on the epitaxial layer and having a second doping type, a first source contact region formed in the epitaxial well region and having the first doping type, a second source contact region formed in the epitaxial well region and having the second doping type, a trench gate formed in the epitaxial well region, a source electrode formed on a side of the epitaxial well region away from the epitaxial layer, and a drain electrode formed on a side of the substrate away from the epitaxial layer, wherein, the trench gate comprises a gate dielectric and a gate electrode, and the silicon carbide trench gate MOSFET further comprises:
a injection-type current diffusion region, which is wrapped around a bottom of the trench gate, and has a concave shape and the first doping type, wherein a bottom of the injection-type current diffusion region is not higher than a bottom of the epitaxial well region, a doping concentration of the injection-type current diffusion region is higher than a doping concentration of the epitaxial layer and a doping concentration of the epitaxial well region, the injection-type current diffusion region is in direct contact with the epitaxial well region, and the bottom of the epitaxial well region is lower than the bottom of the trench gate; and
epitaxial protection regions, which are formed on both sides of the injection-type current diffusion region and at the bottom of the epitaxial well region, and have the second doping type, wherein a bottom of the epitaxial protection region is lower than the bottom of the trench gate.

2. The silicon carbide trench gate MOSFET according to claim 1, wherein the concave shape comprises any one of a U shape, a V shape, a polygon or a rounded rectangle.

3. The silicon carbide trench gate MOSFET according to claim 1, further comprising a shielding region, which is formed in the injection-type current diffusion region and at the bottom of the trench gate, and has the second doping type.

4. The silicon carbide trench gate MOSFET according to claim 1, wherein when the silicon carbide trench gate MOSFET is in a forward conduction state, channels are formed on the both sides of the trench gate, accumulation regions are formed in corners on the both sides of the bottom of the trench gate, and current flows from the drain electrode to the source electrode after passing through the substrate, the epitaxial layer, the injection-type current diffusion region, the accumulation regions, the channels and the first source contact region.

5. A silicon carbide trench gate MOSFET, comprising: a substrate having a first doping type, an epitaxial layer formed on the substrate and having the first doping type, an epitaxial well region formed on the epitaxial layer and having a second doping type, a first source contact region formed in the epitaxial well region and having the first doping type, a second source contact region formed in the epitaxial well region and having the second doping type, a trench gate formed in the epitaxial well region, a source electrode formed on a side of the epitaxial well region away from the epitaxial layer, and a drain electrode formed on a side of the substrate away from the epitaxial layer, wherein the trench gate comprises a gate dielectric and a gate electrode, and the silicon carbide trench gate MOSFET further comprises:
a injection-type current diffusion region, which is wrapped around the bottom of the trench gate, and has a concave shape and the first doping type, wherein a bottom of the injection-type current diffusion region is not higher than a bottom of the epitaxial well region, and a doping concentration of the injection-type current diffusion region is higher than a doping concentration of the epitaxial layer and a doping concentration of the epitaxial well region; and
epitaxial protection regions, which are formed on both sides of the injection-type current diffusion region and at the bottom of the epitaxial well region, and have the second doping type, wherein a doping concentration of the epitaxial protection region is higher than the doping concentration of the epitaxial well region, the injection-type current diffusion region is connected to the epitaxial well region through the epitaxial protection region, and a bottom of the epitaxial protection region is lower than the bottom of the trench gate.

6. The silicon carbide trench gate MOSFET according to claim 5, further comprising a shielding region, which is formed in the injection-type current diffusion region and at the bottom of the trench gate, and has the second doping type.

7. A silicon carbide trench gate MOSFET, comprising: a substrate having a first doping type, an epitaxial layer formed on the substrate and having the first doping type, an epitaxial well region formed on the epitaxial layer and having a second doping type, a first source contact region formed in the epitaxial well region and having the first doping type, a second source contact region formed in the epitaxial well region and having the second doping type, a trench gate formed in the epitaxial well region, a source electrode formed on a side of the epitaxial well region away from the epitaxial layer, and a drain electrode formed on a side of the substrate away from the epitaxial layer, wherein the trench gate comprises a gate dielectric and a gate electrode, and the silicon carbide trench gate MOSFET further comprises:
a injection-type current diffusion region, which is wrapped around the bottom of the trench gate and has a concave shape and the first doping type, wherein a bottom of the injection-type current diffusion region is not higher than a bottom of the epitaxial well region, and a doping concentration of the injection-type current diffusion region is higher than a doping concentration of the epitaxial layer and a doping concentration of the epitaxial well region;
epitaxial protection regions, which are formed on both sides of the injection-type current diffusion region and at the bottom of the epitaxial well region, and have the second doping type, wherein a doping concentration of the epitaxial protection region is higher than the doping concentration of the epitaxial well region, the injection-type current diffusion region is connected to the epitaxial well region through the epitaxial protection region, and a bottom of the epitaxial protection region is lower than the bottom of the trench gate; and
an epitaxial current diffusion region, which is formed above the epitaxial protection region and in the epitaxial well region, and has the first doping type, wherein the epitaxial current diffusion region is in direct contact with sidewalls on the both sides of the trench gate.

8. A method for manufacturing a silicon carbide trench gate MOSFET, comprising:
forming an epitaxial layer on a substrate;
forming an epitaxial well region on the epitaxial layer;
forming a first source contact region in the epitaxial well region;
forming a second source contact region in the epitaxial well region;
etching a trench on a semiconductor surface of the epitaxial well region;
performing ion injection by using a mask of the etched trench, so as to form an injection-type current diffusion region that is wrapped around a bottom of the trench, wherein a bottom of the injection-type current diffusion region is not higher than a bottom of the epitaxial well region, and a doping concentration of the injection-type current diffusion region is higher than a doping concentration of the epitaxial layer and a doping concentration of the epitaxial well region;
forming a gate dielectric on a surface of the trench;
filling the trench with a gate electrode; and
forming a drain electrode on a side of the substrate away from the epitaxial layer and a source electrode on a side of the epitaxial well region away from the epitaxial layer, wherein
the substrate, the epitaxial layer, the first source contact region and the injection-type current diffusion region have a first doping type, and the epitaxial well region and the second source contact region have a second doping type; and
the method further comprises:
growing an epitaxial protection region on a surface of the epitaxial layer, and then continuing to grow the epitaxial well region on a surface of the epitaxial protection region, wherein during a trench etching process, the trench etching process stops in the epitaxial protection region or the epitaxial well region; or
growing the epitaxial protection region on the surface of the epitaxial layer, continuing to grow an epitaxial current diffusion region on the surface of the epitaxial protection region, and then growing the epitaxial well region on the surface of the epitaxial current diffusion region, wherein during the trench etching process, the etching process stops in the epitaxial current diffusion region.

9. The method according to claim 8, wherein performing the ion injection by using the mask of the etched trench, so as to form the injection-type current diffusion region that is wrapped around the bottom of the trench, comprises: forming the injection-type current diffusion region that is wrapped around the bottom of the trench by using the ejection capability of an injection process and the diffusion ability of doped ions.

10. The method according to claim 8, wherein, the epitaxial current diffusion region is formed on the surface of the epitaxial protection region, and the epitaxial well region is formed on the surface of the epitaxial current diffusion region, the method further comprises: forming a third source contact region on an outer side of the epitaxial current diffusion region and above the epitaxial protection region, wherein the second source contact region and the third source contact region are formed by the same ion injection process.
